(19) United States
(12) Patent Application Publication
(10) Pub. No.: US 2009/0014733 A1
(43) Pub. Date: Jan. 15, 2009

(54) LIGHT-EMITTING DIODE MODULE

(75) Inventors: Aldegonda Lucia Weijers, Eindhoven (NL); Martijn Henri Richard Lankhorst, Eindhoven (NL); Lingli Wang, Eindhoven (NL); Teunis Willem Tukker, Eindhoven (NL)

Correspondence Address: PHILIPS INTELLECTUAL PROPERTY & STANDARDS, 3 BURLINGTON WOODS DRIVE, BURLINGTON, MA, 01803, US

(73) Assignee: KONINKLIJKE PHILIPS ELECTRONICS N.V., Eindhoven (NL)

(21) Appl. No.: 12/281,680

(22) PCT Filed: Feb. 27, 2007
(86) PCT No.: PCT/IB2007/050618

§ 371 Date: Sep. 4, 2008

(30) Foreign Application Priority Data
Mar. 6, 2006 (EP) 06110695.1

(51) Int. Cl. H01L 21/50; H01L 33/00

(52) U.S. Cl. 257/89; 438/29; 257/E33.067; 257/E21.499

(57) ABSTRACT

The present invention relates to a light-emitting diode (LED) module (10) comprising a first LED chip (12) for emitting light of a first color, a LED element (14) comprising a second LED chip, which element is placed alongside the first LED chip and adapted to emit light of a second color, and a ceramic conversion plate (16). The ceramic conversion plate covers only a portion of the first LED chip and comprises a wavelength-converting material for converting light emitted from the first LED chip to a third wavelength. The size of the portion of the first LED chip that is covered by the ceramic conversion plate is selected so that the LED module produces mixed light of a certain desired color The present invention also relates to a method of manufacturing such a LED module.

The present invention relates to a light-emitting diode (LED) module comprising a ceramic conversion plate and a method of manufacturing such a LED module.

It is well known in the prior art that light having a first (peak) wavelength can be converted into light having a longer (peak) wavelength by using a process known as luminescence/fluorescence. In the fluorescence process, the light having the first wavelength is absorbed by a wavelength-converting material such as a phosphor, and the luminescent centers of the phosphor material, which emit the light having the longer wavelength, are excited. This process is used in, for example, LEDs to generate white light, wherein emission from a blue LED chip is partly converted to yellow/orange by an overlying phosphor layer, and wherein unconverted blue light and converted yellow/orange light mix to white light.

A recent development in the field of such phosphor-converted LEDs is the use of a ceramic layer as the overlying phosphor layer, as disclosed in the document US2005/0569582. In this document, a light-emitting layer is combined with a ceramic layer which is disposed in the path of the light emitted by the light-emitting layer. The ceramic layer is composed of or includes a wavelength-converting material such as a phosphor. The ceramic layer may be more robust and less sensitive to temperature than other prior-art phosphor layers, which typically comprise a transparent resin, silicon gel, or a similar material as a wavelength-converting material.

US2005/0569582 further discloses an embodiment in which an additional ceramic layer is placed on top of the first ceramic layer, i.e. the two ceramic layers are stacked over the light-emitting layer. The two ceramic layers may comprise different phosphors. The arrangement of different phosphors in the two ceramic layers or of the two ceramic layers themselves may be chosen to control the interaction between the multiple phosphors in the LED module, so that a certain color point can be provided. However, the stacked structure disclosed in US2005/0569582 has the drawback that a ceramic layer combination having specific properties (such as certain phosphor concentrations and/or a certain thickness of the layers) must be produced for each desired overall color point. Also, once the LED module has been manufactured, the opportunity to alter the overall color of the LED module is limited due to the configuration of the ceramic layers. Furthermore, the stacked structure results in a device having a significant height or thickness.

It is an object of the present invention to overcome these problems at least partially, and to provide an improved LED module.

These and other objects that will be evident from the following description are achieved by means of a LED module and a method of manufacturing such a LED module, as defined in the appended claims.

In accordance with an aspect of the invention, a LED module is provided, which comprises a first LED chip for emitting light of a first color, a LED element comprising a second LED chip, which element is placed alongside the first LED chip and adapted to emit light of a second color, and a ceramic conversion plate which covers only a portion of the first LED chip and comprises a wavelength-converting material for converting light emitted from the first LED chip to a third wavelength, wherein the size of the portion of the first LED chip that is covered by the ceramic conversion plate is selected so that the LED module produces mixed light of a certain desired color.

By placing the first LED chip and the LED element alongside each other, i.e. at the same level, and by partly covering the first LED chip with a ceramic conversion plate, the thickness of the device is reduced, while the possibility of providing a certain color point is maintained. Furthermore, the LED module of the invention allows alteration of the overall color of the LED module, even after manufacture of the LED module, because the first LED chip and the LED element can have different electrical settings. This allows use of the LED module in a variable color system wherein the color setting is selected by a user or the system. Furthermore, covering only a portion of the first LED chip with the conversion plate is made possible, or at least facilitated, by the fact that the ceramic conversion plate is a solid-state conversion plate.

For example, the first color may be blue, the second green, and the third red, which colors are mixed to whitish light. Depending on the size of the portion of the first LED chip that is covered by the ceramic conversion plate, the mixed light contains a certain amount of blue and red, yielding a certain overall color or color point.

The size of the portion of the first LED chip that is covered by the ceramic conversion plate is preferably selected by selecting the lateral position of the ceramic conversion plate with respect to the first LED chip, wherein the amount of light that is absorbed and converted from the first LED chip is altered. Here, ceramic conversion plates all having the same size and configuration can be used in the manufacture of LED modules with different color points (simply by selecting a lateral position of the ceramic conversion plate which corresponds to the desired color point), which is very beneficial from a manufacturing point of view.

Alternatively, the size of the portion of the first LED chip that is covered by the ceramic conversion plate may be selected by selecting the size of the ceramic conversion plate or by rotating the ceramic conversion plate.

The LED element may further comprise a layer with a wavelength-converting material for converting light emitted from the second LED chip to a wavelength corresponding to the second color. In this way, both the first and the second LED chips may be of the same type, which is beneficial because both of them will react in the same way to, for example, temperature changes, etc.

In accordance with another aspect of the invention, a method of manufacturing a light-emitting diode (LED) module is provided, which method comprises the steps of providing a first LED chip for emitting light of a first color, providing, alongside the first LED chip, a LED element comprising a second LED chip for emitting light of a second color, and covering only a portion of the first LED chip with a ceramic conversion plate, which plate comprises a wavelength-converting material for converting light emitted from the first LED chip to a third wavelength, wherein the size of the portion of the first LED chip that is covered by the ceramic conversion plate is selected so that the LED module produces mixed light of a certain desired color. This method of manufacturing a LED module offers similar advantages as obtained with the previously described aspect of the invention.

These and other aspects of the present invention will now be described in more detail, with reference to the appended drawings showing currently preferred embodiments of the invention.

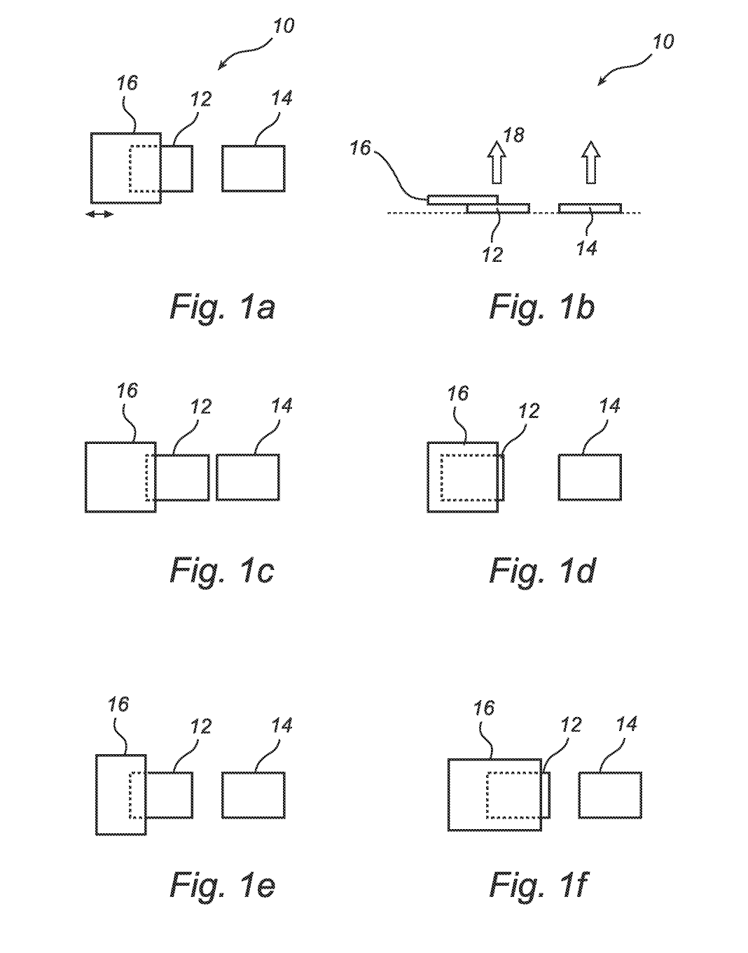

FIGS. 1a-1f illustrate embodiments of a LED module according to the invention,

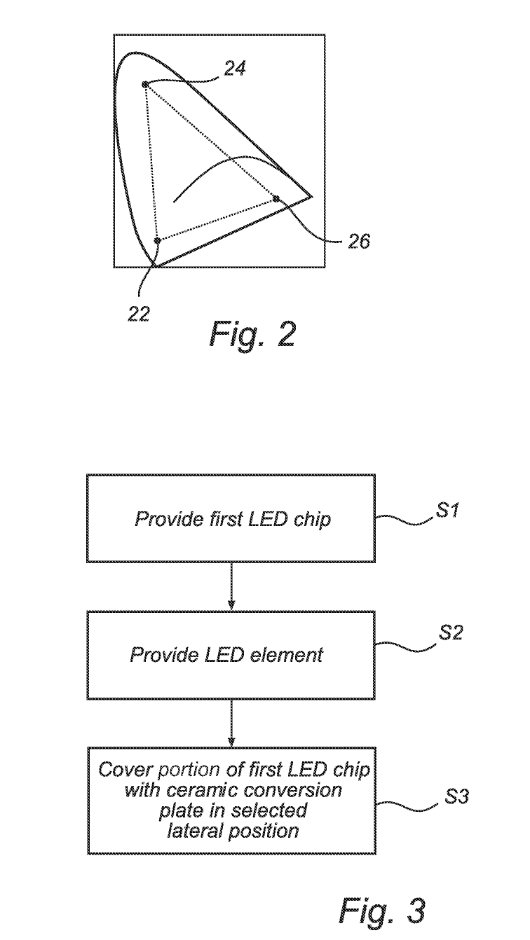

FIG. 2 is a CIE chromaticity diagram for the LED module shown in FIGS. 1a-1f, and

FIG. 3 is a flow chart of a method of manufacturing a LED module according to the invention.

FIGS. 1a-1f illustrate embodiments of a LED module 10 according to the invention. FIG. 1a is a top view and FIG. 1b is a side view of a basic configuration of the LED module 10. The LED module 10 comprises a first LED chip 12 adapted to emit blue light, and a LED element 14 provided alongside the first LED chip 12, which element is adapted to emit green light. The first LED chip 12 is advantageously positioned close to the LED element 14. The LED module 10 further comprises a ceramic conversion plate 16 covering a portion of the first LED chip 12, i.e. the ceramic conversion plate 16 is disposed partly in a path of light (indicated by arrow 18 in FIG. 1b) emitted from the LED chip 12. The first LED chip 12 may be, for example, a blue LED chip, and the LED element 14 may be a blue LED chip (second LED chip) covered by a phosphor layer (not shown) adapted to absorb the blue light from the underlying blue LED chip and convert it to e.g. green light. The phosphor layer may be a ceramic conversion plate. The ceramic conversion plate 16 comprises a wavelength-converting material, such as a phosphor, for converting at least a portion of light emitted from the first LED 12 chip to red light. The ceramic conversion plate 16 may be of a similar material as that of the ceramic layers in US2005/0569582 mentioned above.

During operation, converted red light from the ceramic conversion plate 16 is thus mixed with unconverted blue light from the portion of the first LED chip 12 not covered by the ceramic conversion plate 16 and unconverted green light from the LED element 14, wherein a whitish light having a certain color point is produced.

However, by altering the size of the portion of the first LED chip 12 covered by the ceramic conversion plate 16, the LED module 10 can be tuned so that a different color point can be provided. This can be achieved, for example, by shifting the lateral position of the ceramic conversion plate 16 with respect to the first LED chip 12. In FIG. 1c, the ceramic conversion plate 16 is shifted to the left, so that less blue light from the first LED chip 12 is converted into red light by the ceramic conversion plate 16, while the green content remains constant, resulting in an increased color temperature of the overall mixed light. This can be explained with reference to the CIE chromaticity diagram in FIG. 2, wherein the first LED chip 12, the LED element 14, and the ceramic conversion plate 16 emit light with color coordinates 22, 24, 26 that are blue, green, and red, respectively. When the red ceramic conversion plate 16 is shifted over the blue LED chip 12, the LED module 10 can adopt white color points along the axis between the blue and red color coordinates 22, 26 in the CIE chromaticity diagram shown in FIG. 2. Specifically, when the ceramic conversion plate 16 is shifted to the left in FIG. 1c, the LED module's overall color point moves to the left in the CIE chromaticity diagram in FIG. 2.

In contrast to FIG. 1c, the ceramic conversion plate 16 in FIG. 1d is shifted to the right, so that more blue light from the first LED chip 12 is converted into red light by the ceramic conversion plate 16, while the green content again remains constant, resulting in a decreased color temperature of the overall mixed light.

Alternatively, or as a complement, the size of the ceramic conversion plate 16 can be altered in order to influence the color temperature of the LED module's overall emission. In FIG. 1e, the size of the ceramic conversion plate 16 is decreased as compared with the ceramic conversion plate 16 in the basic configuration in FIGS. 1a-1b, while the size of the ceramic conversion plate 16 in FIG. 1f is increased. Such sizing of the ceramic conversion plate 16 yields the same result regarding the color temperature of the overall mixed light as previously described with reference to FIGS. 1c and 1d, respectively.

Selecting the lateral position of the ceramic conversion plate 16 with respect to the first LED chip 12 and/or sizing of the ceramic conversion plate 16 is preferably carried out during manufacture of the LED module 10. The former option offers a significant advantage in that ceramic conversion plates all having the same configuration can be used in the manufacture of LED modules with different color points, simply by laterally shifting the ceramic conversion plate with respect to the first LED chip so as to obtain the desired overall color point, as explained above.

A method of manufacturing a LED module according to the invention is summarized by way of example in the flow chart shown in FIG. 3. The method comprises the steps of providing the first blue LED chip 12 (S1), providing a green LED element 14 (S2) alongside the first LED chip 12, and covering only a portion of the first LED chip 12 with the red ceramic conversion plate 16 (S3), wherein the lateral position of the ceramic conversion plate 16 with respect to the LED 12 chip is selected so that the LED module 10 produces mixed light of a certain desired color.

It should be noted that the “colors” of the LED element 14 and the ceramic conversion plate 16 in FIGS. 1a-1d can be switched, so that the LED element 14 is adapted to emit red light, and the ceramic conversion plate 16 is adapted to convert blue light from the first LED chip 12 to green light. In this case, shifting the green ceramic conversion plate 16 over the blue LED chip 12 has the result that more or less blue is converted to green, so that the overall color of the LED module is influenced, i.e. when the green ceramic conversion plate 16 is shifted over the blue LED chip 12, the LED module can adopt white color points along the axis between the blue and green color coordinates 22, 24 in the CIE chromaticity diagram shown in FIG. 2. In the same way as above, the LED element can be a blue LED chip (second LED chip) covered by a phosphor layer adapted to absorb blue light from the underlying blue LED chip and convert it to red light.

It should also be noted that, in the LED module according to the invention, it is also possible to significantly influence the overall color point after manufacture by independently altering the electrical settings of the LED chip 12 and the second LED chip of the LED element 14. This allows the LED module according to the invention to be used in a color-variable system.

Other applications of the LED module according to the invention include LCD monitors or LCD televisions, general lighting applications, beamers, direct-view applications, etc.

The person skilled in the art will realize that the present invention is by no means limited to the preferred embodiments described above and that many modifications and variations are possible within the scope of the appended claims. For example, even though the above examples relate to red, green and blue, other colors are within the scope of the invention, such as yellow, orange, UV-radiation, cyan, etc. Also, more than three colors can be mixed in the LED module, for example, by adding additional LED chips/LED elements of different colors.

1. A light-emitting diode (LED) module comprising:
(a) a first LED chip for generating first radiation having a first spectrum corresponding to a first color,
(b) an LED element adapted to emit light of a second color, the LED element comprising a second LED chip for generating second radiation having a second spectrum different from the first spectrum the second LED chip disposed adjacent to the first LED chip, and
(c) a conversion plate covering only a portion of the first LED chip and comprising a first wavelength-converting ceramic material for altering at least one wavelength component of the first spectrum so as to provide a third spectrum, wherein the size of the portion of the first LED chip covered by the conversion plate is selected so that the LED module produces mixed radiation having a combined spectrum corresponding to a predetermined color.

2. A LED module according to claim 1, wherein the size of the portion of the first LED covered by the conversion plate is selected by selecting the lateral position of the conversion plate with respect to the first LED chip.

3. A LED module according to claim 1, wherein the LED element comprises a second wavelength-converting material for altering at least one wavelength component of the second spectrum so as to provide a fourth spectrum corresponding to that of the second color.

4. A method of manufacturing a light-emitting diode (LED) module, the method comprising the steps of:
(a) providing a first LED chip for generating first radiation having a first spectrum corresponding to a first color,
(b) disposing, adjacent to the first LED chip, an LED element adapted to emit light of a second color, the LED element comprising a second LED chip for generating second radiation having a second spectrum different from the first spectrum, and
covering only a portion of the first LED chip with a conversion plate comprising a first wavelength-converting ceramic material for altering at least one wavelength component of the first spectrum so as to provide a third spectrum, wherein the size of the portion of the first LED chip covered by the conversion plate is selected so that the LED module produces mixed radiation having a combined spectrum corresponding to a predetermined color.

5. A method according to claim 4, wherein the size of the portion of the first LED chip covered by the conversion plate is selected by selecting the lateral position of the conversion plate with respect to the first LED chip.
